(19) United States
(12) Patent Application Publication
(10) Pub. No.: US 2007/0115010 A1
(43) Pub. Date: May 24, 2007

(54) Connection accessory for micro-probing

(76) Inventors: Michael T. McTigue, Colorado Springs, CO (US); James E. Cannon, Black Forrest, CO (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/284,548

(22) Filed: Nov. 22, 2005

(51) Int. Cl. G01R 31/02

(52) U.S. Cl. 324/754

(57) ABSTRACT

A probing system has a probing accessory for electrically connecting to a complementary probe accessory connected to a test point where the probing accessory captures and releases the complementary probe accessory by application of only tensile forces.

### BACKGROUND

As operating frequencies of electronic circuits increase and component geometries decrease, it gets more difficult to probe and measure signals from test points on a printed circuit board (PCB). In addition, the devices used to probe the test points begin to have an effect on the measurement itself. One current solution is to provide one or more header pins that connect to a socketed probe head. The header pins are typically 25 mils square on 100 mils centers. In many applications, these header pins are too physically large and present too much parasitical loading and therefore limit the bandwidth of a signal that may be measured. As geometries of a printed circuit board get smaller, the header pins take up a larger percentage of the PCB surface area which is costly and limits the miniaturization of the device that uses the PCB. Another known solution is to solder probe heads directly to test points on the PCB. Advantageously, the soldered probe head provides for a lower capacitance and a higher bandwidth connection. Disadvantageously, the solution is costly, does not provide for quick easy connection/disconnection, and the number of times it can be soldered and un-soldered is limited.

There is a need, therefore, for a connection accessory that addresses the disadvantages of the prior art.

### BRIEF DESCRIPTION OF THE DRAWINGS

An understanding of the present teachings can be gained from the following detailed description, taken in conjunction with the accompanying drawings of which:

FIG. 1 is an enlarged perspective view of an embodiment of a probe head and complementary probing accessory according to the present teachings in an unmated condition.

FIG. 2 is an enlarged perspective view of an embodiment of a probe head and complementary probing accessory according to the present teachings in an mated condition.

FIG. 3 is a conceptual view of a printed circuit board with an embodiment of connection accessories according to the present teachings installed.

FIG. 4 is a graph of the tensile forces applied to the probe head to connect and disconnect a connection accessory according to the present teachings.

FIG. 5 is an enlarged perspective view of another embodiment of a probe head according to the present teachings in an unmated condition.

### DETAILED DESCRIPTION

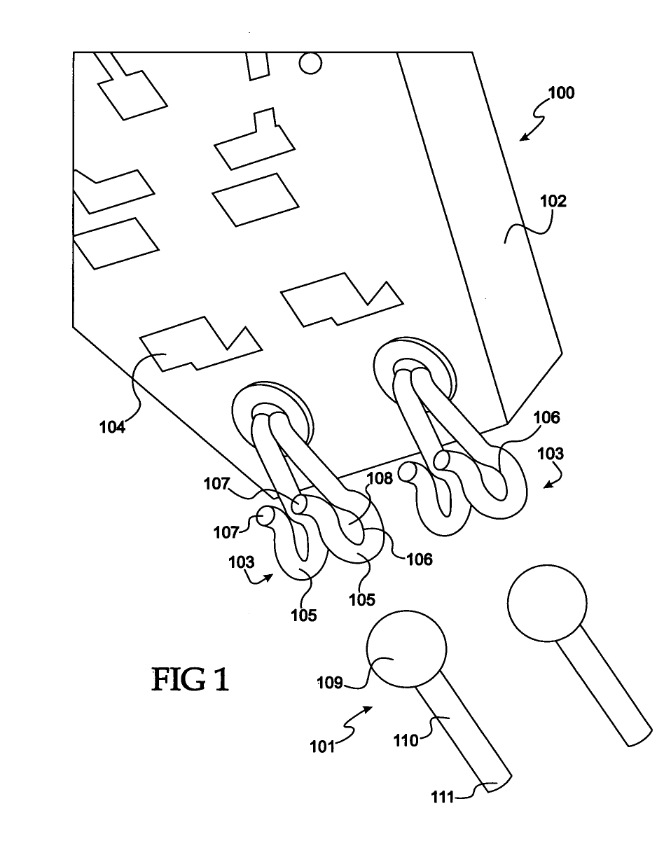

With specific reference to FIG. 1 of the drawings, there is shown an enlarged perspective view of a probe head 100 and complementary probing accessory 101 according to the present teachings. The probe head 100 makes electrical connection to a differential signal and, therefore, includes two identical connections for each one of the differential ports. The probe head 100 includes a housing 102 that holds two capture elements 103. Each capture element 103 is connected to an impedance element 104 that is electrically disposed between the capture element 103 and the remainder of the probe circuitry in the probe head 100. The impedance element 104 is typically a resistance to damp the connection parasitics as is known to one of ordinary skill in the art. The remainder of the probe circuitry is similar to that disclosed in U.S. patent application Ser. No. 10/829,725 entitled “Compliant Micro-Browser For A Hand Held Probe” filed Apr. 22, 2004 and U.S. patent application Ser. No. 10/945,146 entitled “High Frequency Oscilloscope Probe With Unitized Probe Tips” filed Sep. 20, 2004 the contents of which are incorporated by reference herein. The capture elements 103 include respective spring elements 105. In a specific embodiment, each spring element 105 comprises a wire formed into approximately 330 degrees of a circle to create an open loop 106. Ends 107 of the wire distal from the housing 102 of the probe head 100 are disposed external of the open loop 106 to form a “V” with a large opening end of the “V” disposed away from a center opening 108 of each open loop 106. The center opening 108 of each open loop 106 is sized and configured to capture a retention element 109. A distance between the spring elements 105 in a single capture element 103 is shortest at an end that connects to the housing and gradually increases to a largest distance at an end further from the housing 102. In a specific embodiment, the final length of each of the capture elements 103 is 60 mils.

In a specific embodiment, the retention element 109 is a sphere mechanically and electrically connected or unitary with an extension shaft 110. An attachment end 111 of the extension shaft 110 is electrically and mechanically connected via solder or other known electrical/mechanical connection to a test point on a test device such as a printed circuit board (“PCB”). In a specific embodiment, the sphere 109 is metal and approximately 15 mils in diameter and the extension shaft 110 is unitary with the sphere 109 and is approximately 7 mils in diameter.

As one of ordinary skill in the art appreciates, an extension shaft 110 of the example diameter is not able to take any compressive force without damage to the complementary probe accessory 101. Because the extension shaft 110 is metal, however, one of ordinary skill in the art can further appreciate that it is able to accept and withstand a tensile force without damage.

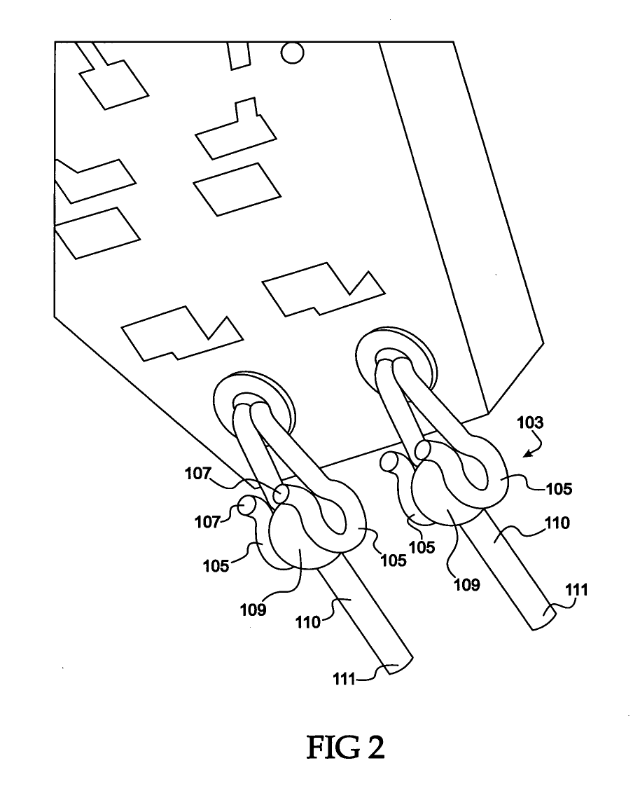

A method of connection between the capture element 103 and the complementary probe accessory 101 further illustrates the relationship between the capture elements 103 and the retention element 109. Specifically, the method of connection for the embodiment illustrated in FIG. 1 of the drawings comprises positioning the capture elements 103 close to the attachment end 111 of the extension shaft 110 so that the sphere 109 is free of the capture elements 103, but the extension shaft 110 is positioned between the capture elements 103. Because of the relative sizes between the diameter of the extension shaft 110 and the distance between the capture elements 103 distal from the housing 102, there is room to position the two as described with some margin of adjustment. Minimal tensile force is applied in the process just described. FIG. 2 of the drawings shows the capture elements 103 retaining the sphere 109 as described.

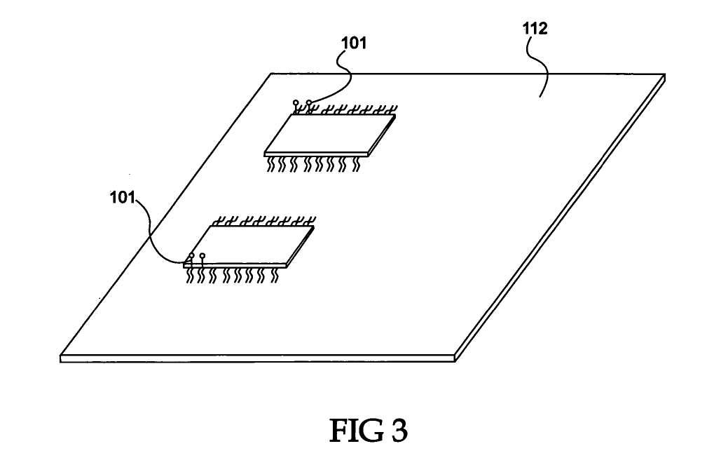

With specific reference to FIG. 3 of the drawings, there is shown a diagram that is more suggestive than it is illustrative of a complementary probe accessory 101 soldered to a PCB 112. FIG. 3 of the drawing is included herein to place the present teachings in the context of its application.

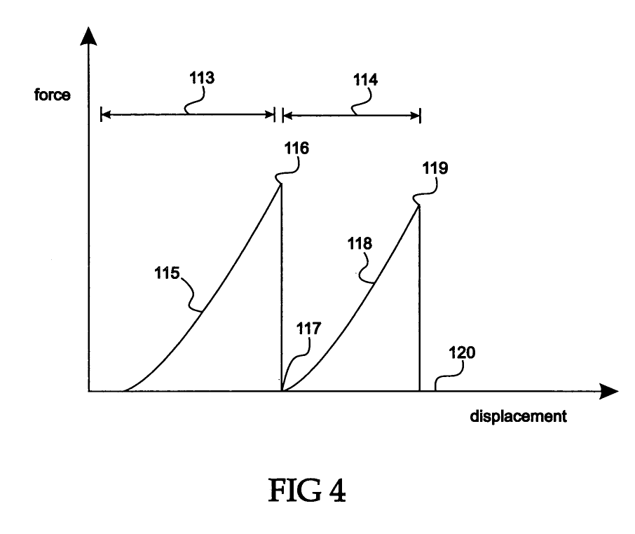

With specific reference to FIG. 4 of the drawings, there is shown a graph of the tensile forces applied during connection 113 and disconnection 114 of a probe system according to the present teachings as a function of displacement between the capture elements 103 and the sphere 109. Once positioned, the capture elements 103 are moved away from the attachment end 110 of the extension shaft 110 until the larger open portion of the “V” disposed away from the open loop 106 of each capture element 103 engages the surface of the sphere 109. As additional and an increasing first tensile force 115 is applied to the probe head 100, the “V” guides the sphere 109 towards a position that is central to the capture elements 103. The surface of the sphere 109 in combination with the first tensile force 115 causes displacement of the capture elements 103 outwardly to accept the full diameter of the sphere 109. As further tensile force is applied to the probe head 100, the sphere 109 is fully accepted 116 into the space between the capture elements 103. Because the spring elements 103 are biased inwardly, they return to a neutral position 117 thereby retaining the sphere 109 when something less than a threshold tensile force is applied.

The capture elements 103 and the sphere 109 are made of electrically conductive material. Accordingly, the retention of the sphere 109 between the capture elements 103 provides electrical continuity between the test point on the PCB 112 and the circuitry in the probe head 100 that performs the probing function. When the sphere 109 is captured between the capture elements 103, the sphere 109 is able to swivel as it is retained between the capture elements 103 without loss of mechanical or electrical connection. The swivel provides some allowance for movement 117 as the probe head 100 is bumped or wiggled that serves to minimize stress that may be applied to the solder connection between the extension shaft 110 and the PCB while still providing a reliable electrical and mechanical connection between the probe head 100 and the test point.

A method of disconnection between the probe head 100 and the complementary probe accessory comprises applying a second tensile force 118 to the probe head in the same direction as the first tensile force 115 applied to perform the capture. With specific reference to FIG. 4 of the drawings, application of the second tensile force 118 after the sphere 109 is captured between the capture elements 103 causes a portion of the open loop 106 that is distal from the housing 102 and opposite the “V” to engage the sphere 109. The surface of the sphere 109 causes the capture elements 103 to displace outwardly from each other until the full diameter of the sphere 109 is free 119 of the capture elements 103. The sphere 109 is then able to fully disengage 120 from the capture elements 103 to remove the electrical and mechanical connection between the probe head 100 and complementary probe accessory 101.

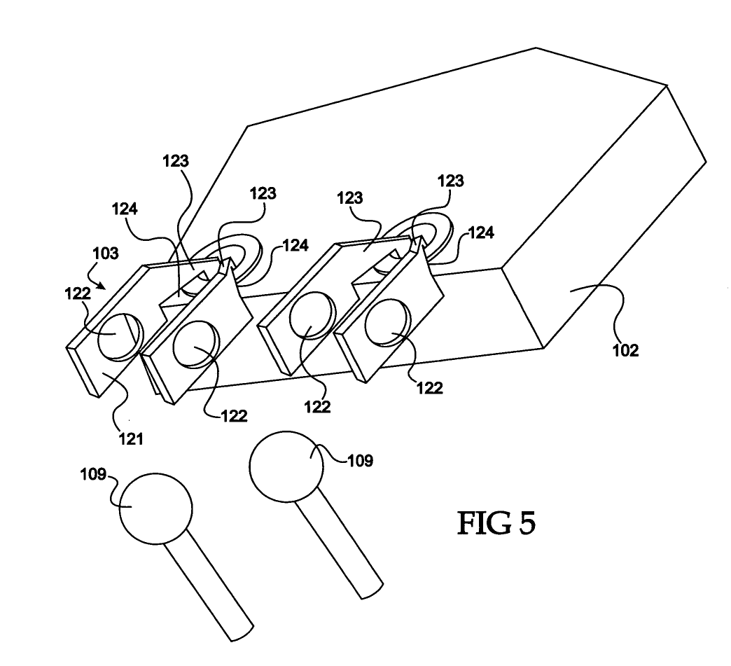

With specific reference to FIG. 5 of the drawings, there is shown an alternative embodiment of capture elements 103 according to the present teachings that comprise two plates 121 with a detent 122 to capture the sphere 109. In a specific embodiment, the detent 122 can also be an opening or other relief area to allow room to capture the retention element when the capture elements 103 return to their neutral position. The capture plates 121 perform the same function as the embodiment of capture elements 103 illustrated in FIGS. 1 & 2 of the drawings. The capture plates 121 extend past capture arms 123 that connect to the probe head 102. The capture arms 123 angle away from each other and attach or are unitary with the capture plates 121. The capture plates 121 are parallel to each other. Relief areas 124 in the capture arms 123 permit positioning of the retention elements 109 prior to application of the first tensile force 115 that captures and retains the retention elements 109 within the openings 122 in the capture plates. The capture plates 121 act as spring elements that are biased inwardly as the surface of the sphere 109 forces them outwardly. When the full diameter of the sphere 109 reaches the detent or opening 122, the capture plates 121 return to their neutral position thereby capturing the sphere 109. The second tensile force 118 forces the sphere 109 past the detent or opening 122 to a point where the sphere 109 is free of the capture plates 121. The capture plates 121 then return to their neutral position as the sphere 109 is free of the capture plates 121.

Other embodiments not specifically illustrated will occur to one of ordinary skill in the art with benefit of the present teachings and are considered within the scope of the appended claims. The retention element disclosed is a sphere, but could also have another suitable geometry for a given application such as elliptical, cylindrical or pill shaped. Embodiments disclosed may be differently scaled depending upon requirements of a particular application.

1. A probing system comprising:
A probing accessory configured to be mechanically affixed and electrically connected to a test point, the probing accessory comprising a probe retention element disposed on an extension shaft, and
a probe head configured to capture and release the retention element using only tensile force on the probing accessory.

2. A probing system as recited in claim 1 wherein the retention element is spherical.

3. A probing system as recited in claim 1 wherein a width of the probe retention element is greater than a width of the extension shaft.

4. A probing system as recited in claim 2 wherein the retention element has a diameter in a range of approximately 10-20 mils and the connection shaft has a width in a range of approximately 5-10 mils.

5. A probing system as recited in claim 1 wherein the probe head further comprises a capture element configured to position the retention element and then accept the retention element upon application of a first tensile force.

6. A probing system as recited in claim 5 wherein the capture element is further configured to release the retention element upon application of a second tensile force.

7. A probing system comprising:
A probe accessory for electrically connecting to a test point, and
A means on a probe head for capturing and releasing the probe accessory by application of only tensile forces.

8. A probing system as recited in claim 6 wherein the probe accessory comprises a retention element mechanically and electrically connected to the test point and the means for capturing and releasing comprises a capture element that accepts the retention element upon application of a first tensile force.

9. A probing system as recited in claim 8 wherein the retention element is spherical.

10. A probing system as recited in claim 8 wherein the capture element releases the retention element upon application of a second tensile force.

11. A probing system as recited in claim 6 wherein the probe accessory is a sphere and the means for capturing and releasing comprises two spring elements configured to capture the sphere between them.

12. A probing system as recited in claim 11 each spring element comprises a wire formed into an open loop and configured to capture the sphere between them.

13. A probing system as recited in claim 11 each spring element comprises a plate with a detent.

14. A method for probing a test point comprising the steps of:
mechanically and electrically connecting a retention element to the test point,
positioning a capture element over the retention element and
applying a first tensile force until the capture element accepts and retains the retention element.

15. A method as recited in claim 14 and further comprising the step of applying a second tensile force until the retention element is free of the capture element.

16. A method as recited in claim 14 wherein the retention element is a sphere.

17. A method as recited in claim 16 wherein the capture element comprises a wire formed into an open loop.

18. A method as recited in claim 16 wherein the capture element comprises a plate having a detent.
